(19) United States
(12) Patent Application Publication
(10) Pub. No.: US 2014/0367854 A1
(43) Pub. Date: Dec. 18, 2014

(54) INTERCONNECT STRUCTURE FOR MOLDED IC PACKAGES

(71) Applicant: Broadcom Corporation, Irvine, CA (US)

(72) Inventors: Sam Ziqun Zhao, Irvine, CA (US); Rezaur Rahman Khan, Irvine, CA (US)

(21) Appl. No.: 13/927,470

(22) Filed: Jun. 26, 2013

Related U.S. Application Data
(60) Provisional application No. 61/835,933, filed on Jun. 17, 2013.

(51) Int. Cl. H01L 23/00

(52) U.S. Cl. CPC H01L 24/14; H01L 24/97
USPC 257/738; 438/113

(57) ABSTRACT

Various examples are provided for interconnection structures for molded IC packages. In one example, among others, an IC package includes a substrate and an interposer. A plurality of conductive elements provide physical and electrical contact between a surface of the substrate and a surface of the interposer. A standoff element disposed between the surfaces of the substrate and interposer provides a minimum spacing between the surfaces of the substrate and interposer. In some implementations, a standoff element is disposed between an IC die disposed on the surface of the substrate and the surface of the interposer. In another example, a method includes coupling conductive elements to a surface of an interposer, attaching a standoff element, coupling the conductive elements to a surface of a substrate, and forming an embedded layer between the interposer and substrate. The standoff element defines a minimum gap between the interposer and the substrate.

### CROSS REFERENCE TO RELATED APPLICATIONS

This application claims priority to co-pending U.S. provisional application entitled “Interconnect Structure for Molded IC Packages” having Ser. No. 61/835,933, filed Jun. 17, 2013, the entirety of which is hereby incorporated by reference.

### BACKGROUND

In a stacked integrated circuit (IC) package, package-to-package interconnection can be facilitated by mounting a top package to the substrate of a bottom package. Exposed land pads on a top surface of the substrate of the bottom package can provide contact points for solder balls on the top package. The exposed solder ball land pads are located along the periphery of the top surface of the substrate and surround the package molding compound. The top package can be attached to the bottom package using conventional reflow surface mount processes.

### BRIEF DESCRIPTION OF THE DRAWINGS

Many aspects of the present disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views.

FIG. 1 is a cross-sectional diagram illustrating an example of a portion of an IC package in accordance with various embodiments of the present disclosure.

FIG. 2 is an image of a cross-sectional view of an example of an IC in accordance with various embodiments of the present disclosure.

FIG. 3 includes images of examples of conductive regions on a surface of an IC package in accordance with various embodiments of the present disclosure.

FIG. 4 is an image of a cross-sectional view of an example of vertical interconnection within an IC package in accordance with various embodiments of the present disclosure.

FIG. 5 is a cross-sectional diagram illustrating an example of a portion of an IC package including standoff elements in accordance with various embodiments of the present disclosure.

FIGS. 6A-6D are graphical representations of locations of standoff elements in an IC package of FIG. 5 in accordance with various embodiments of the present disclosure.

FIGS. 7A-7D are cross-sectional diagrams illustrating examples of a portion of an IC package including standoff elements in accordance with various embodiments of the present disclosure.

FIGS. 8A-8B and 9A-9B are examples of fabrication of an IC package with standoff elements in accordance with various embodiments of the present disclosure.

FIG. 10 is a flow diagram illustrating an example of fabrication or manufacturing of an IC package with standoff elements in accordance with various embodiments of the present disclosure.

### DETAILED DESCRIPTION

Disclosed herein are various embodiments related to interconnect structures for molded integrated circuit (IC) packages. Reference will now be made in detail to the description of the embodiments as illustrated in the drawings, wherein like reference numbers indicate like parts throughout the several views.

Stacked IC packages allow for the vertical integration of active and passive components within a single package. Stacked IC packages including an interposer stacked on a substrate can facilitate, e.g., (1) system in package (SiP) technology, (2) package-on-package (PoP) vertical interconnection technology of ball grid array (BGA) packages, (3) low profile package PoP design, (4) stacking of chip-scale packages, and (6) high speed communication applications. Stacked IC package designs can also mitigate or reduce electromagnetic interference (EMI) and/or enhance thermal performance for IC packages. Stacked IC packages may be utilized in a variety of applications including, but not limited to, mobile applications such as hand-held communication devices (cell phones, global positioning devices, watch-size communication devices, etc.), mobile multimedia (video/audio) players, wireless personal area networking devices such as a Bluetooth headset, and flash memory devices such as memory cards.

Integration of packages is desirable to enable small electronic devices for these applications. For example, the substrate may be configured to support baseband and/or broadband processing circuitry and/or one or more application processor(s). In addition, the interposer may be configured to support different type of device packages such as, e.g., one or more discrete memory packages and/or radio frequency (RF) front end packages. For instance, the interposer 109 can support multimode and/or multiband power amplification circuitry and/or antenna switch circuitry (e.g., SAW filters and/or duplexers). More than one package can be mounted on the interposer. Traces on the interposer 109 may also be used to implement antenna(s) and/or antenna array(s). Baluns for wireless applications and passive components such as, e.g., capacitors, inductors, and resistors can also be mounted on the interposer.

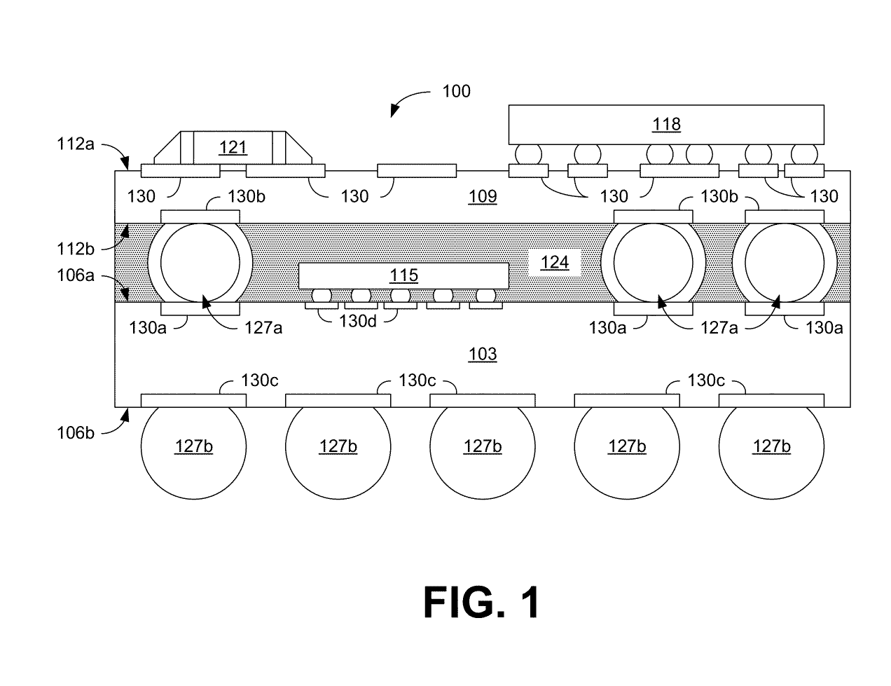

Referring to FIG. 1, shown is a cross-sectional diagram illustrating an example of a portion of an IC package 100 in accordance with various embodiments of the present disclosure. The IC package 100 of FIG. 1 includes a substrate 103 with opposing surfaces. In the example of FIG. 1, the substrate 103 includes a first (e.g., top) surface 106a and a second (e.g., bottom) surface 106b. The substrate 103 can include one or more dielectric layers that are interdigitized, e.g., sandwiched, between one or more metal layers. The material of each dielectric layer may be one of a variety of different types of dielectric materials such as, e.g., FR-4. In some implementations, different dielectric materials may be used for the dielectric layers. The metal layers can include one or more variety of different types of metals, e.g., copper or aluminum. One or more of the metal layers may be patterned to include trace(s), conductive regions (e.g., bond or land pad(s)), and/or other components. Vias may be used to electrically couple between various metal layers.

The IC package 100 of FIG. 1 also includes an interposer 109, which comprises a substrate that provides an interface structure for vertical interconnection of, e.g., PoP technologies. The interposer 109 includes opposing surfaces with a first (e.g., top) surface 112a and a second (e.g., bottom) surface 112b. The interposer 109 can include one or more dielectric layers that are interdigitized, e.g., sandwiched, between one or more metal layers. The material of each dielectric layer may be one of a variety of different types of dielectric materials such as, e.g., FR-4. The metal layers can include one or more variety of different types of metals, e.g., copper or aluminum. One or more of the metal layers may be patterned to include trace(s), conductive regions, and/or other components. Vias may be used to electrically couple between various metal layers. The substrate 103 and interposer 109 may be formed out of the same materials (e.g., the same dielectric material and/or metal) or may be formed out of different materials and can include different numbers of metal layers.

Active and/or passive devices may be embedded between the substrate 103 and interposer 109. For example, one or more IC dies 115 may be disposed on the first surface 106a of the substrate 103 and/or on the second surface 112b of the interposer 109. IC dies 115 may be connected to, e.g., the first surface 106a using, e.g., flip chip or wire bond connections. Active and/or passive devices may also be mounted on the first surface 112a of the interposer 109. For example, the devices can include one or more IC dies 118 in ball grid array (BGA) package, passive components 121 (e.g., a balun, a capacitor, an inductor, or a resistor), and/or an antenna (not shown). The antenna may be formed from traces on the second surface 112b of the interposer 109.

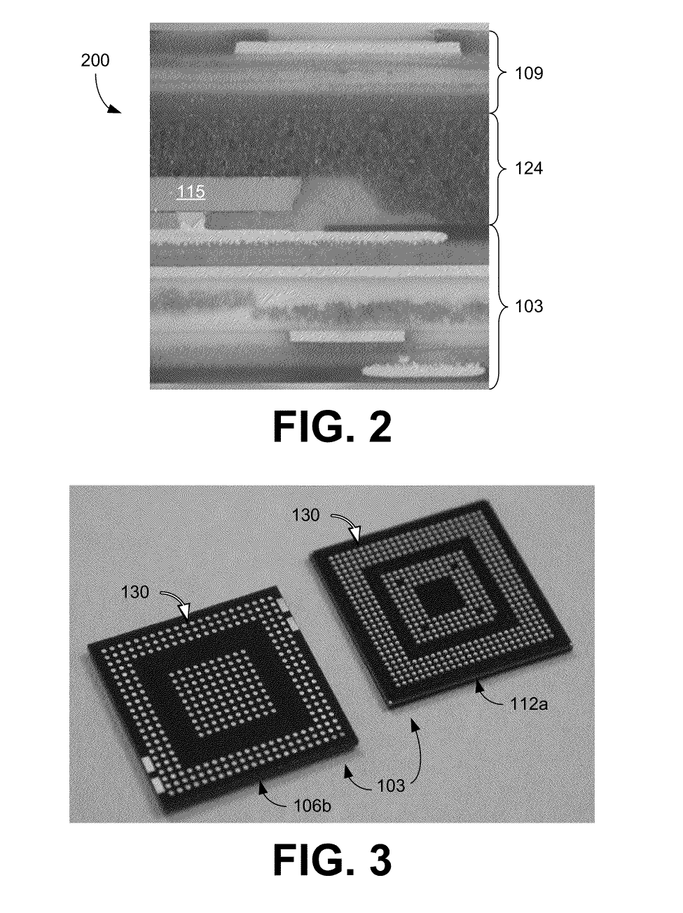

Encapsulation material may be disposed between the substrate 103 and interposer 109 to form an embedded layer 124. The encapsulation material encapsulates active and/or passive devices (e.g., IC die 115) between the substrate 103 and interposer 109. By injecting the encapsulation material using, e.g., film assisted vacuum molding, voids can be eliminated between the substrate 103 and interposer 109. FIG. 2 is an image of a cross-sectional view of an example of an IC package 200 (Warpage and Electrical Performance of Embedded Device Package, MCeP by Tanaka et al., Electronic Components and Technology Conference (ECTC), May 2011). The IC package 200 of FIG. 2 includes a substrate 103 comprising a plurality of dielectric and metal layers, an interposer 109 comprising a plurality of dielectric and metal layers, and an embedded layer 124 surrounding an IC die 115.

Referring back to FIG. 1, conductive elements 127 can be used to provide electrically coupling for the substrate 103 and/or interposer 109 through conductive regions 130 on a surface of the substrate 103 and/or interposer 109. Conductive elements 127 may include a variety of different types of conductive elements such as, e.g., solder balls, bumps, posts, pads, pins, and/or pillars. In the example of FIG. 1, the conductive elements 127 include homogeneous and/or non-homogeneous solder balls. For example, a first plurality of conductive elements 127a may comprise non-homogeneous solder balls in contact with a plurality of conductive regions 130a (e.g., ball pads) on the first surface 106a of the substrate 103 and a plurality of conductive regions 130b on the second surface 112b of the interposer 109. In some implementations, the non-homogeneous solder balls may be copper core solder balls comprising a copper core and an outer shell or coating of solder. The copper core can prevent collapse of the solder ball and thus maintain the distance between the substrate 103 and interposer 109 during molding of the embedded layer 124. After molding, the conductive elements 127a may be entirely encapsulated in the encapsulation material of the embedded layer 124. The solder shell can provide a physical connection with the conductive regions 130a and 130b.

Other conductive elements 127 can be used to provide electrically coupling to other devices coupled to conductive regions 130 of the substrate 103 and/or interposer 109. Conductive elements 127 can be used provide connections to active and/or passive components (e.g., 115, 118, and 121) disposed on the first surface 106a of the substrate 103, the first surface 112a of the interposer 109, and/or the second surface 112b of the interposer 109. For example, one or more IC dies 115 may be disposed on the first surface 106a of the substrate 103 using, e.g., solder balls as illustrated in FIG. 1. Connections may be made through conductive regions 130d (e.g., ball pads or bump pads) using flip chip or wire bond techniques. In addition, conductive elements 127b may be used to facilitate communication between the IC package 100 and a printed circuit board (PCB) (not shown). For example, a plurality of conductive elements 127a may comprise solder balls in contact with a plurality of conductive regions 130a on the second surface 106a of the substrate 103. The solder balls can be used to provide a ball grid array (BGA) configured to contact conductive regions on the PCB. Elements such as, e.g., traces can provide electrical coupling to other devices coupled to the PCB. In some implementations, a first IC die 115 can include a processor and a second IC die 118 can include a memory. The processor included in the first IC 115 die can be configured to store data in the memory included in the second IC die 118.

FIG. 3 is an image of examples of conductive regions 130 (e.g., in a BGA) on a first surface 112a of an interposer 109 (FIG. 1) and a second surface 106b of a substrate 103 (FIG. 1) (Warpage and Electrical Performance of Embedded Device Package, MCeP by Tanaka et al., Electronic Components and Technology Conference (ECTC), May 2011). For example, the inner conductive regions 130 on the interposer 109 of FIG. 3 may be used for connections to an IC die 115 (FIG. 1) and the outer conductive regions 130 of FIG. 3 may be used for connections to an interposer 109 (FIG. 1). Conductive regions 130 on the second side 106b of the substrate 103 can be connected to conductive regions 130 on the first side 106a of the substrate 103 through metal layers and/or vias in the substrate 103.

Mounting the conductive elements 127 to the interposer 109 (FIG. 1) facilitates the vertical interconnection with the substrate 103. The substrate 103 has conductive regions 130 (e.g., land pads, ball pads, bump pads, etc.) on the first surface 106a (FIG. 1), which provide contact with the conductive elements 127 (e.g., solder balls) on the interposer 109. The conductive regions 130a (FIG. 1) can be located along the periphery of the substrate 103 as shown in FIG. 3 and can surround the conductive regions 130 for mounting one or more IC dies 115 or other active and/or passive devices. For example, the conductive regions 130a may be ball pads while the conductive regions The interposer 109 can be attached to the substrate 103 using conventional reflow surface mount processes. This configuration can reduce overall package stack height by placing the IC die 115 (FIG. 1) within a window opening in the substrate center.

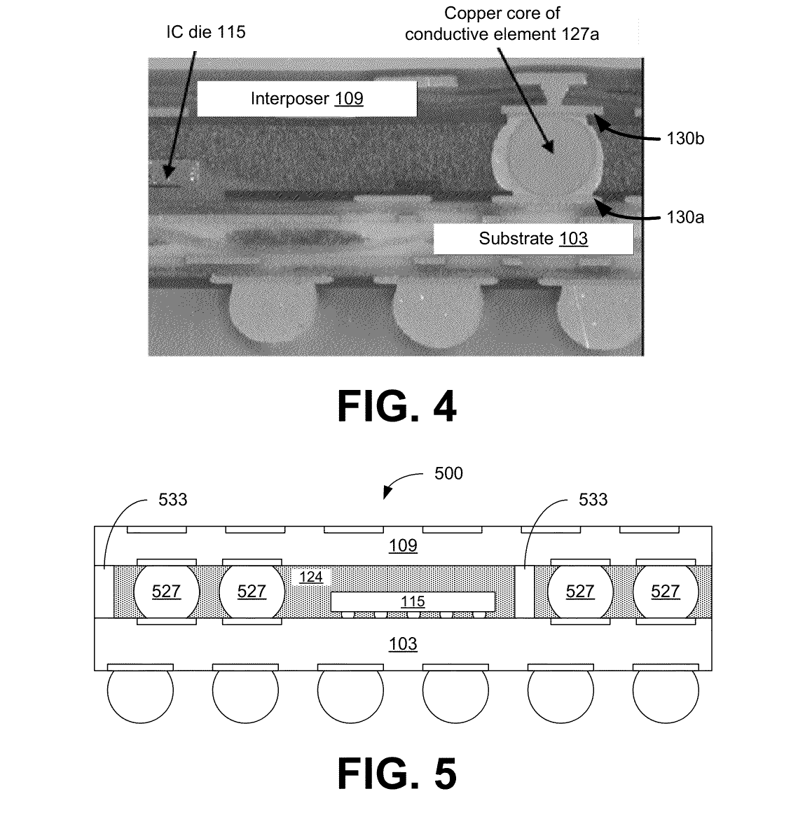

Copper core solder balls with a copper ball within the solder coating can provide a minimum spacing between the substrate 103 and interposer 109. FIG. 4 shows a cross-sectional view of an example of vertical interconnection using a conductive element 127a with a copper core (Warpage and Electrical Performance of Embedded Device Package, MCeP by Tanaka et al., Electronic Components and Technology Conference (ECTC), May 2011). Mechanical and electrical connection to the conductive region 130a of the substrate 103 and the conductive region 130b of the interposer 109 is provided by the solder coating surrounding the copper core. During the reflow process, the solder coating bonds with the conductive regions 130a. In some cases, the solder flows down the copper core from the upper joint due to gravity as shown in FIG. 4. The solder loss from the upper joint can result in a weak mechanical connection and can be prone to open joints with little or no connectivity. In addition, copper core solder balls can be expensive when compared with conventional homogeneous solder balls.

Using homogeneous solder balls for the conductive elements 127 can be advantageous. Spacing between the substrate 103 and interposer 109 can be maintained by introducing one or more standoff elements 533 between the substrate 103 and interposer 109. A standoff element 533 prevents the collapse of the interposer 109 on the IC die 115 or other active and/or passive elements mounted between the substrate 103 and interposer 109. Examples of standoff elements include, but are not limited to, standoff posts which may be made of dummy silicon, solder masks, passive components (e.g., capacitors or resistors), etc. The height of the standoff element 533 may be selected to maintain a minimum and/or constant mold flow gap between the interposer 109 and an IC die 115 disposed on the substrate 103. Similarly, the height of the standoff element 533 may be selected to maintain a minimum and/or constant mold flow gap between the substrate and an IC die 115 disposed on the interposer 109.

Referring to FIG. 5, shown is a cross-sectional diagram illustrating an example of a portion of an IC package 500 in accordance with various embodiments of the present disclosure. In the example of FIG. 5, the IC package 500 includes a substrate 103 and interposer 109. Conductive elements 527 comprising homogeneous solder balls provide physical and electrical contact between the substrate 103 and the interposer 109. One or more IC dies 115 may be disposed on the substrate 103 as shown in FIG. 5. For example, the IC die 115 may include a processor or an application specific IC (ASIC). To maintain an appropriate gap between the substrate 103 and interposer 109, and thus between the IC die 115 and the interposer 109, one or more standoff elements 533 can be located within the package. For example, the standoff elements of FIG. 5 may be standoff posts made of dummy silicon that are attached to the second (e.g., bottom) surface of the interposer 109. The standoff element(s) 533 may be strategically located in open spaces between the substrate 103 and interposer 109. For instance, standoff elements 533 may be located near a package corner and/or near a corner of an IC die 115 to ensure proper spacing between the IC die 114 and interposer 109 or the substrate 103 and the interposer 109. In the example of FIG. 5, standoff elements 533 are located in an open area adjacent to the IC die 115. Standoff elements may also be located over a trace on the substrate 103 surface if made of nonconductive material or insulated from the trace.

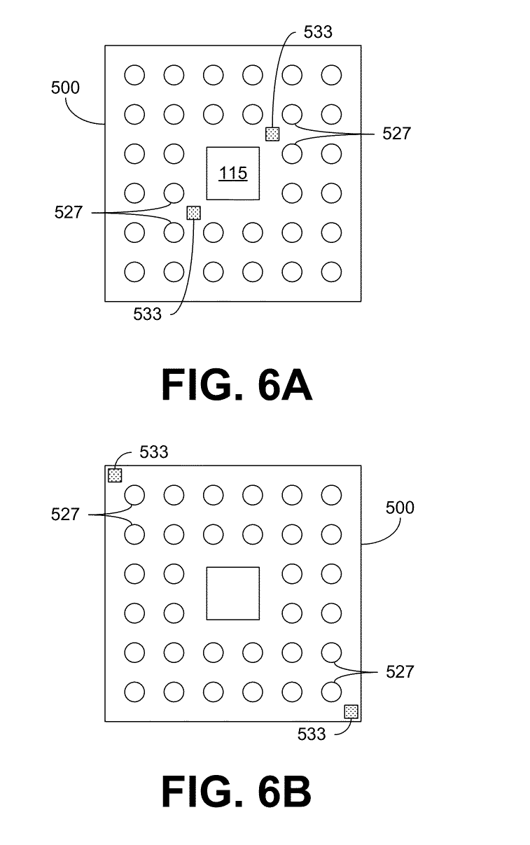

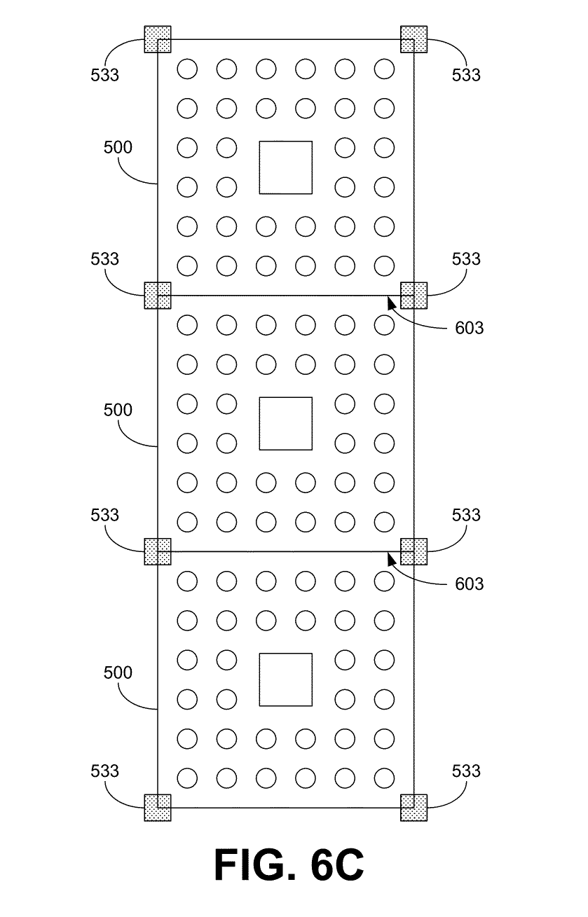

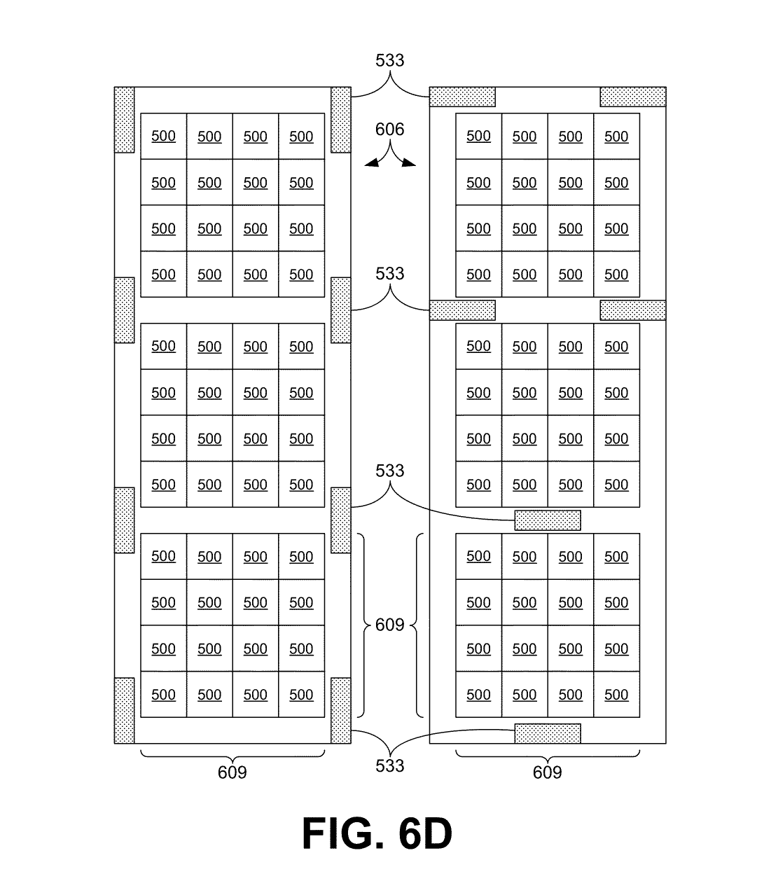

Standoff elements 533 are attached before stacking of the interposer 109 on the substrate 103. FIGS. 6A-6D are graphical representations of examples of various locations of standoff elements 533 within an IC package 500 or within a sheet of IC packages 500 before singulation. One or more standoff elements 533 can be positioned in the open space between the IC die 115 and the inner row of conductive elements 527 as shown in FIG. 6A. In the example of FIG. 6A, the standoff elements 533 are positioned near the die corners. One or more standoff elements 533 may also be positioned at the edge of the IC package 500, outside the outer row of conductive elements 527 as shown in FIG. 6B. In the example of FIG. 6B, the standoff elements 533 are positioned near the IC package corners. The standoff elements within the IC package 500 are encapsulated in the embedded layer 124 (FIG. 5).

Standoff elements 533 can also be positioned as a combination of FIGS. 6A and 6B. Standoff elements 533 may also be located between rows of conduction elements 527 and/or on a BGA grid. Standoff elements 533 may also be located on the package singulation cut sheet 603 as illustrated in FIG. 6C. In some implementations, a portion of the standoff element 533 lies within the package area and a portion is outside the package area and will not be retained after singulation.

In some cases, one or more standoff elements 533 may be located outside the IC package 500 during fabrication. The standoff elements outside the IC package 500 can provide a minimum and/or constant gap between the substrate 103 and interposer 109 while the encapsulation material is injected (e.g., using film assisted vacuum molding) to form the embedded layer 124. After the formation of the embedded layer 124, the standoff elements outside the IC package may then be removed during singulation of the IC package 500. Referring to FIG. 6D, shown are examples of substrate strips 606 including substrate blocks 609 of IC packages 500 with the standoff elements 533 located outside the IC packages 500.

As illustrated in the examples of FIG. 6D, the standoff elements 533 may be positioned along the outer edge of the substrate strip 606 at transitions between the substrate blocks 609. The standoff elements 533 may also be positioned to extend from the edge of the substrate strip 606 between the substrate blocks 609 or may be located at other positions between the substrate blocks 609. During singulation of the IC packages, the standoff elements 533 will be removed. In some implementations, a combination of one or more standoff element 533 located within the IC package 500 and one or more standoff element 533 located outside the IC package 500 may be used during fabrication.

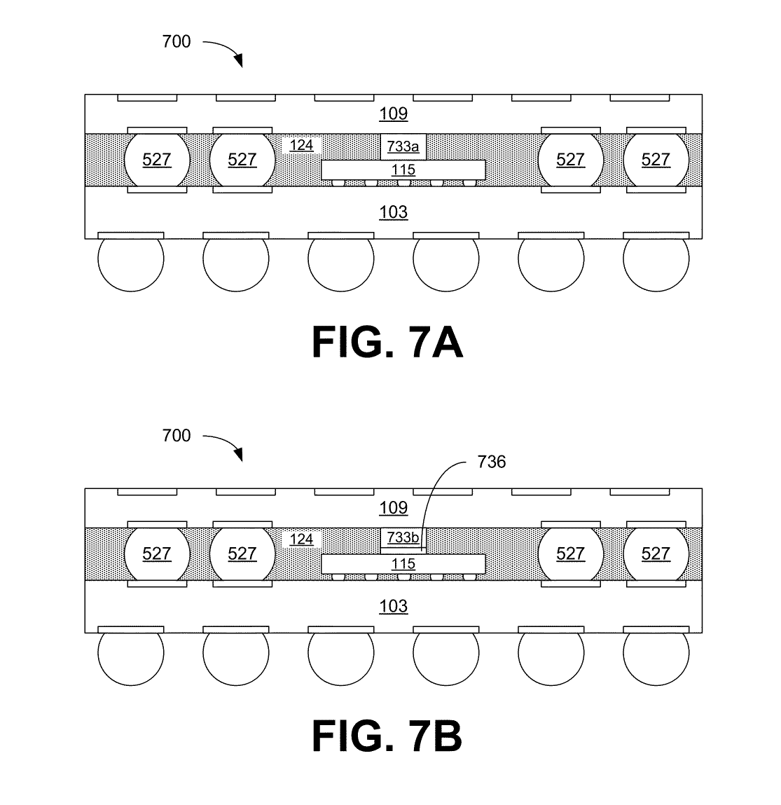

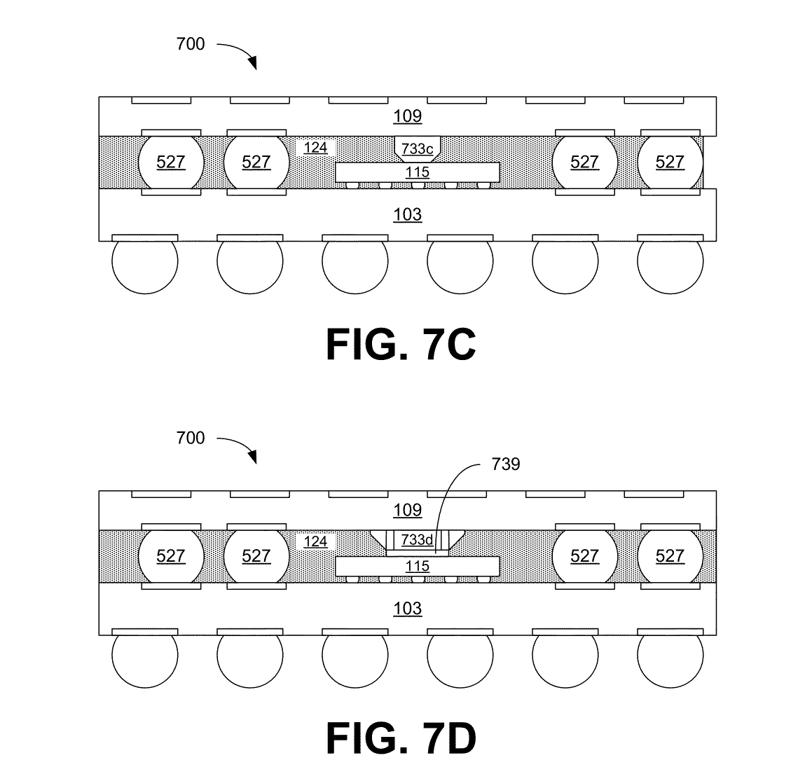

In some embodiments, a standoff element may be located between the interposer 109 and the IC die 115. Referring now to FIGS. 7A-7D, shown are examples of an IC package 700 with a standoff element 733 disposed between the IC die 115 and the interposer 109. In the example of FIG. 7A, the standoff element 733a may be one or more standoff post made of dummy silicon that is attached to the second (e.g., bottom) surface of the interposer 109. The standoff element 733a may be approximately centered over the IC die 115. The standoff element 733a maintains the appropriate gap between the interposer 109 and the IC die 115 during fabrication of the IC package 700. In the example of FIG. 7B, the standoff element 733b may be one or more standoff post made of dummy silicon that is attached to the top of the IC die 115. A die attach material 736 such as, e.g., a film, epoxy, or other appropriate material may be used to affix the standoff element 733b to the IC die 115. The standoff element 733b may be approximately centered on the IC die 115 to maintain a minimum distance between the interposer 109 and the IC die 115 during fabrication of the IC package 700.

Referring next to FIG. 7C, the standoff element 733c may be one or more solder mask that protrudes from the second (e.g., bottom) surface of the interposer 109. The solder mask may be produced by printing a plurality of layers on the interposer substrate to achieve the desired height for the gap between the interposer 109 and the IC die 115. In the example of FIG. 7D, the standoff element 733d may be a passive component (e.g., a capacitor or resistor) that is attached to conductive regions on the second (e.g., bottom) surface of the interposer 109. An insulating layer 739 may be disposed on the standoff element 733d to protect the IC die 115 from the passive element. As discussed above, standoff elements 733 are attached before stacking of the interposer 109 on the substrate 103 and carrying out the reflow mounting process. In some implementations, a combination of one or more standoff element 533 extending between the substrate 103 and the interposer 109 and one or more standoff element 733 located between the IC die 115 and the interposer 109 is used.

As noted above, examples of standoff elements 533/733 include, but are not limited to, standoff posts which may be made of dummy silicon, solder masks, passive components, and other materials including copper, aluminum, metal alloys, and ceramic materials, etc. In some cases, metal standoff posts and/or a surface of the substrate 103 and/or interposer 109 may be insulated for protection. Standoff posts can include an adhesive coating on one surface for attachment to the substrate 103 or interposer 109 (FIGS. 1 and 5). Passive components such as, e.g., capacitors, resistors, or other passive elements may be used as a standoff element 533/733. An insulating layer may be provided to provide isolation between the passive component and another passive element, active element, IC die, or trace on the opposing substrate. In some cases, dummy (or non-functioning) capacitors or other passive elements, which are secured to the substrate 103 and/or interposer 109, may be used as a standoff element 533/733. In other implementations, dummy silicon attached to an interposer 109 substrate or on an IC die 115 (FIGS. 7A-7D) such as, e.g., an ASIC or other processor circuitry implemented in an IC die can be used as standoff elements 733.

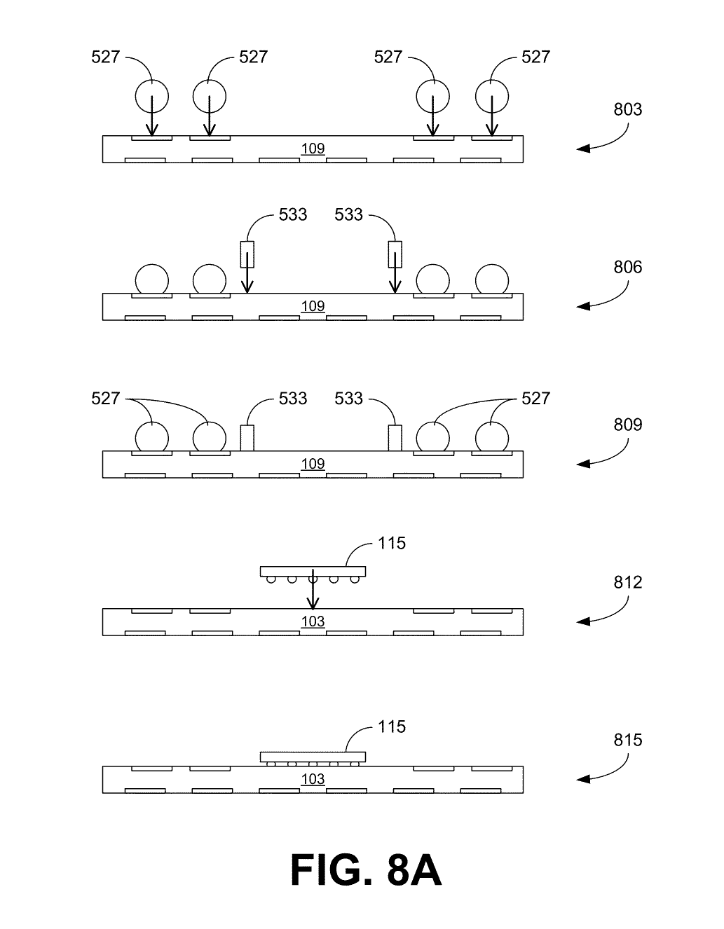

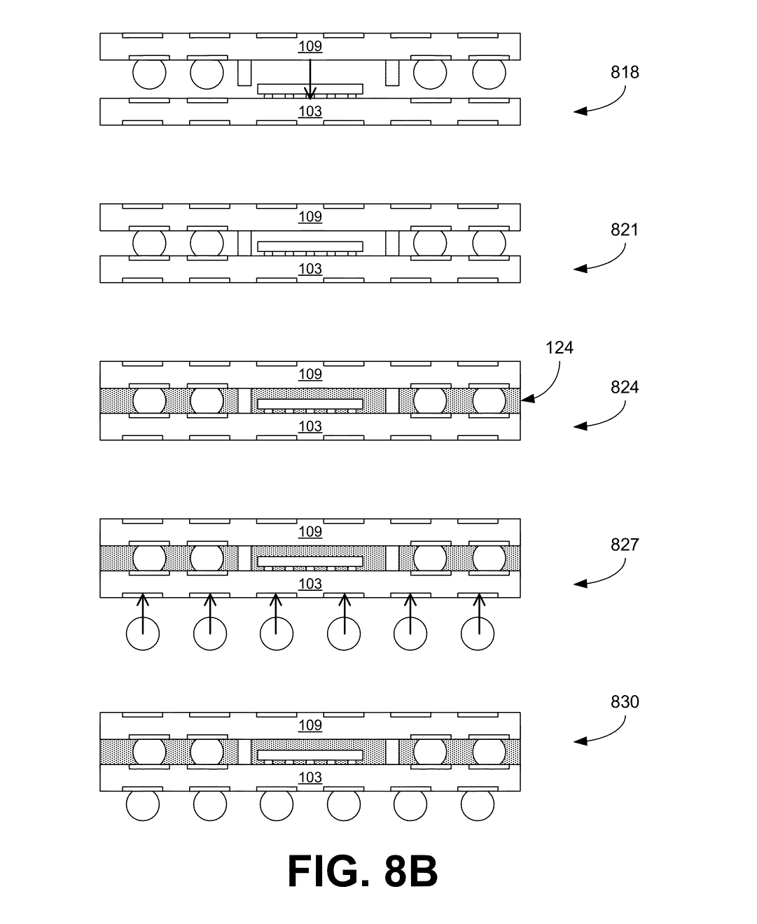

Referring next to FIGS. 8A and 8B, shown is an example of fabrication or manufacturing of an IC package using a standoff element in accordance with various embodiment of the current disclosure. Beginning in FIG. 8A, conductive elements 527 are attached to the substrate of the interposer 109 as illustrated at 803. For example, a plurality of homogeneous solder balls can be attached to conductive regions on a bottom side of the interposer substrate to form a BGA. Passive elements such as, e.g., capacitors and/or resistors may also be attached to the bottom side of the interposer substrate at 803 (not shown). In some implementations, a passive element (e.g., a capacitor or resistor) may be used as a standoff element. Insulating layers may be formed on the passive element to achieve the desired height for the minimum gap distance. Next, standoff elements such as, e.g., one or more standoff posts are attached to the bottom side of the interposer 109 as illustrated at 806. For example, the standoff post may include an adhesive coating suitable for securing the standoff post on the substrate of the interposer 109. The interposer 109 with conductive elements 527 and standoff elements 533 attached is shown at 809.

One or more IC dies 115 (or other active or passive components) may be attached to the top side of the substrate 103 as illustrated at 812. For example, homogeneous solder bumps/balls may be used to attach a flip chip IC die 115 to the substrate 103. In some implementations, standoff elements 533 may be attached to the substrate 103 at 812. The substrate 103 with the IC die attached is shown at 815. Attachment of the IC die 115 (and standoff elements 533) to the substrate 103 may be carried out in parallel with the attachment of the conductive elements 527 and/or standoff elements 533 at 803 and 806.

Moving to FIG. 8B, the interposer 109 (with conductive elements 527 and standoff elements 533) is stacked on the substrate 103 (with IC die 115) as illustrated at 818. The conductive elements 527 on the interposer 109 are aligned with conductive regions on the substrate 103. A reflow surface mount process can be carried out at 821 to connect the interposer 109 to the substrate 103 via, e.g., homogeneous solder balls. The homogeneous solder balls provide electrical connection between the substrate 103 and the interposer 109. Encapsulation material is injected between the substrate 103 and interposer 109 to form an embedded layer 124 using a mold encapsulation process such as film assisted vacuum molding as illustrated at 824. The standoff elements 533 ensure that a minimum distance is maintained between the interposer 109 and substrate 103 and/or between the interposer 109 and IC die 115 during molding. The encapsulation material is then injected to seal the space between the interposer 109 and the substrate 103, thereby encapsulating the conductive elements 527 (e.g., homogeneous solder balls), IC die 115 and/or other components disposed between the substrate 103 and interposer 109. By maintaining the appropriate gap between the substrate 103 and interposer 109, use of the standoff elements 533 can ensure that the proper amount of encapsulation material is injected between the substrate 103 and interposer 109, which can prevent voids from forming during the molding process.

Additional conductive elements may be attached on the bottom side of the substrate 103 to form a package BGA as illustrated at 827. Other components such as, e.g., one or more additional IC die, passive component and/or active component may be attached to the top side of the interposer 109 at 830. In addition, singulation of the IC package can occur at 830. If one or more of the standoff elements 533 are located outside the IC package, then they are removed at 830 during singulation.

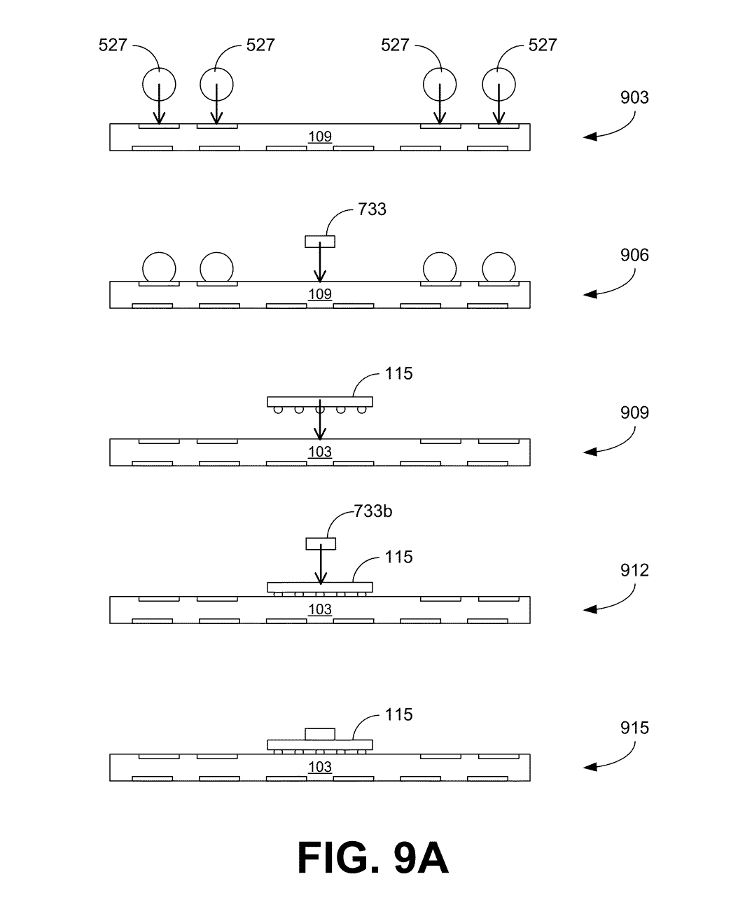

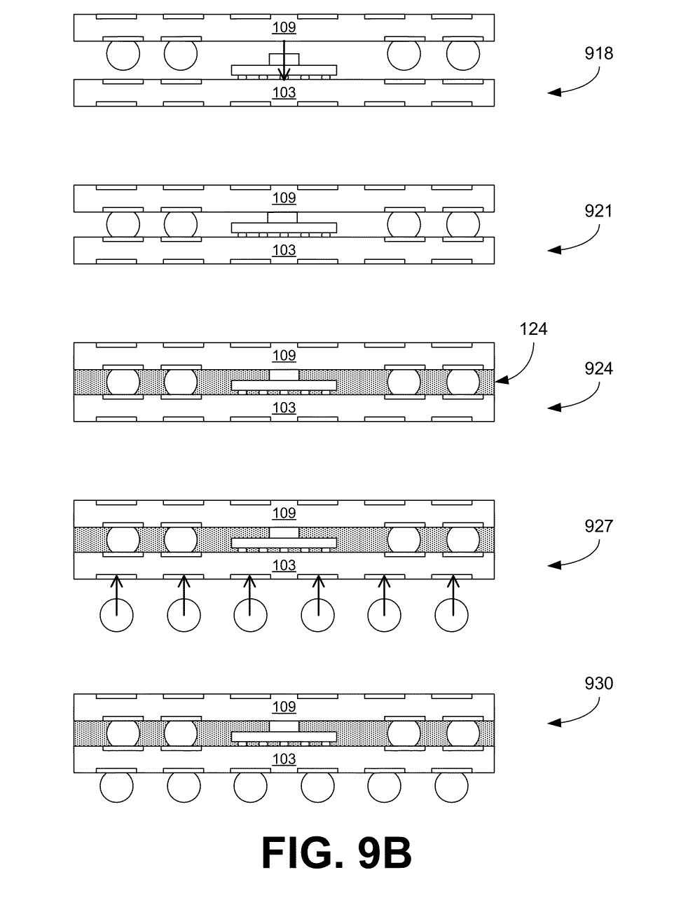

Referring now to FIGS. 9A and 9B, shown is another example of fabrication or manufacturing of an IC package using a standoff element in accordance with various embodiment of the current disclosure. Beginning in FIG. 9A, conductive elements 527 are attached to the substrate of the interposer 109 as illustrated at 903. For example, a plurality of homogeneous solder balls can be attached to conductive regions on a bottom side of the interposer substrate. If a standoff element 733 such as, e.g., a standoff post made of dummy silicon (FIG. 7A), is to be attached to the interposer 109, then the standoff element 733 is attached as illustrated at 906 of FIG. 9A. For example, the standoff post may include an adhesive coating suitable for securing the standoff post on the substrate of the interposer 109. Other standoff elements 733 such as, e.g., a solder mask (FIG. 7C) and/or a passive element (FIG. 7D) may be attached to the interposer 109 at 906. In some implementations, an insulating layer may be applied to the standoff element 733 to ensure isolation of the IC die 115.

One or more IC dies 115 (or other active or passive components) may be attached to the top side of the substrate 103 as illustrated at 909. For example, a flip chip IC die 115 may be attached to the substrate 103. If a standoff element 733 such as, e.g., a standoff post made of dummy silicon of FIG. 7A, is to be attached to the IC die 115, then the standoff element 733 is attached as illustrated at 912 of FIG. 9A. A die attach material such as, e.g., a film, epoxy, or other appropriate material may be used to affix the standoff element 733 to the IC die 115. The substrate 103 with the IC die and standoff element attached is shown at 915. Attachment of the IC die 115 to the substrate 103 and/or standoff element 733 may be carried out in parallel with the attachment of the conductive elements 527 at 903.

Moving to FIG. 9B, the interposer 109 (with conductive elements 527) is stacked on the substrate 103 (with IC die 115 and standoff element 733) as illustrated at 918. The conductive elements 527 on the interposer 109 can be aligned with the corresponding conductive contact pads on the substrate 103. A reflow surface mount process can be carried out at 921 to connect the interposer 109 to the substrate 103 via, e.g., homogeneous solder balls. The homogeneous solder balls provide electrical connection between the substrate 103 and the interposer 109. Encapsulation material is injected between the substrate 103 and interposer 109 to form an embedded layer 124 using a molding process such as, e.g., film assisted vacuum molding as illustrated at 924. The standoff elements 533 ensure that a minimum distance is maintained between the interposer 109 and IC die 115 and/or between the interposer 109 and substrate 103 while a vacuum is applied. The encapsulation material is then injected to seal the space between the interposer 109 and the substrate 103, thereby encapsulating the conductive elements 527 (e.g., homogeneous solder balls), IC die 115 and/or other components disposed between the substrate 103 and interposer 109. By maintaining the appropriate gap between the IC die 115 and interposer 109, use of the standoff elements 533 can ensure that the proper amount of encapsulation material is injected between the substrate 103 and interposer 109, which can prevent voids from forming during the molding process.

Additional conductive elements may be attached on the bottom side of the substrate 103 to form a package BGA as illustrated at 927. Other components such as, e.g., one or more additional IC die, passive component and/or active component may be attached to the top side of the interposer 109 at 930. In addition, singulation of the IC package can occur at 930. If one or more of the standoff elements 733 are located outside the IC package, then they are removed at 930 during singulation.

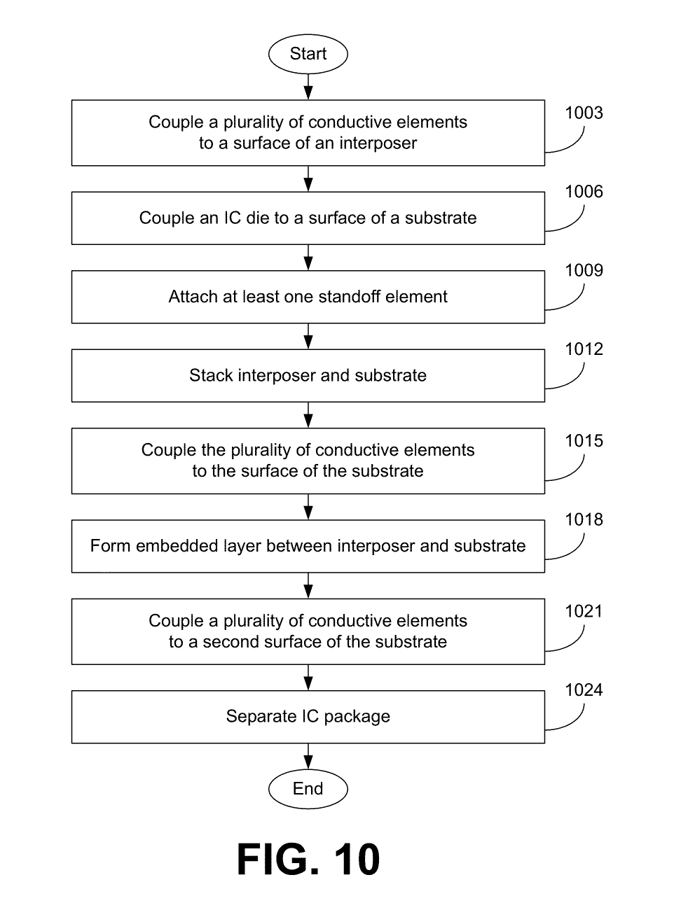

FIG. 10 is a flow diagram illustrating an example of fabrication or manufacturing of an IC package with standoff elements in accordance with various embodiments of the present disclosure. Beginning at 1003, a plurality of conductive elements can be coupled to a surface of an interposer 109 (FIGS. 8A and 9A). For example, homogeneous solder balls may be attached to conductive regions on the surface of the interposer 103. At 1006, an IC die 115 can be coupled to a surface of a substrate 103 (FIGS. 8A and 9A). The IC die 115 may be attached to conductive regions on the surface of the substrate 103 in parallel with attaching the plurality of conductive elements to the surface of the interposer 109. In some implementations, the conductive elements may be mounted to the substrate 103 after the IC die 115 is attached (e.g., flip chip) to the substrate 103.

At least one standoff element 533/733 (FIGS. 8A and 9A) can be attached in 1009. In some implementations, the standoff element 533/733 is attached to the surface of the interposer 109 (FIGS. 5, 7A, 7C and 7D). The standoff element 533 may be attached within or outside of the IC package area (FIGS. 6A-6D). In other implementations, the standoff element 733 may be attached to a surface of the IC die 115 (FIG. 7B). At 1012, the interposer 109 and substrate 103 can be stacked (FIGS. 8B and 9B). The plurality of conductive elements on the surface of the interposer 109 can be aligned with conductive regions on the surface of the substrate 103. The height of the standoff element(s) defines a minimum or constant spacing or gap between the surface of the interposer 109 and the surface of the substrate 103.

At 1015, the plurality of conductive elements can be coupled to the surface of the substrate 103. For example, a reflow mounting process may be used to couple homogenous solder balls to the substrate 103. The plurality of conductive elements can provide physical and electrical contact between the substrate 103 and the interposer 109. An embedded layer 124 may then be formed between the interposer 109 and substrate 103 at 1018 (FIGS. 8B and 9B). Encapsulation material can be injected to form the embedded layer between the surface of the interposer and the surface of the substrate using, e.g., film assisted vacuum molding. The embedded layer encapsulates the plurality of conductive elements, the IC die 115 and/or the standoff element(s) 533/733 and is in contact with the surface of the interposer and the surface of the substrate.

A plurality of conductive elements may be coupled to a second side of the substrate at 1021 (FIGS. 8B and 9B). For example, a plurality of homogeneous solder balls may be attached to conductive regions on the second side of the substrate 103 to form a BGA for connection with, e.g., a PCB. In addition, other active elements, passive elements, and/or IC dies may be coupled to a second side of the interposer 109 as illustrated in FIG. 1. At 1024, the IC package is separated during singulation. Standoff elements that are located outside the IC package area are removed during singulation while standoff elements within the package area remain encapsulated within the embedded layer 124.

It should be emphasized that the above-described embodiments of the present disclosure are merely examples of implementations set forth for a clear illustration of the principles of the disclosure. Many variations and modifications may be made to the above-described embodiment(s) without departing substantially from the spirit and principles of the disclosure. All such modifications and variations are intended to be included herein within the scope of this disclosure and protected by the following claims.

It should be noted that ratios, concentrations, amounts, and other numerical data may be expressed herein in a range format. It is to be understood that such a range format is used for convenience and brevity, and thus, should be interpreted in a flexible manner to include not only the numerical values explicitly recited as the limits of the range, but also to include all the individual numerical values or sub-ranges encompassed within that range as if each numerical value and sub-range is explicitly recited. To illustrate, a concentration range of “about 0.1% to about 5%” should be interpreted to include not only the explicitly recited concentration of about 0.1 wt % to about 5 wt %, but also include individual concentrations (e.g., 1%, 2%, 3%, and 4%) and the sub-ranges (e.g., 0.5%, 1.1%, 2.2%, 3.3%, and 4.4%) within the indicated range. The term “about” can include traditional rounding according to significant figures of numerical values. In addition, the phrase “about ‘x’ to ‘y’” includes “about ‘x’ to about ‘y’”.

Therefore, at least the following is claimed:

1. An integrated circuit (IC) package, comprising:
a substrate including a first surface and a second surface opposite the first surface;
an interposer including a first surface and a second surface opposite the first surface;
a plurality of homogeneous solder balls disposed between the first surface of the substrate and the second surface of the interposer, the plurality of homogeneous solder balls providing physical and electrical contact between the substrate and the interposer; and
a standoff element disposed between the first surface of the substrate and the second surface of the interposer, the standoff element providing a predefined minimum spacing between the first surface of the substrate and the second surface of the interposer.

2. The IC package of claim 1, further comprising an IC die disposed between the first surface of the substrate and the second surface of the interposer.

3. The IC package of claim 2, wherein the standoff element is located between the IC die and an inner row of the homogenous solder balls.

4. The IC package of claim 2, wherein the standoff element is located between an outer row of the homogenous solder balls and an outer edge of the IC package.

5. The IC package of claim 1, further comprising a plurality of standoff elements disposed between the first surface of the substrate and the second surface of the interposer, the plurality of standoff elements providing a predefined minimum spacing between the first surface of the substrate and the second surface of the interposer.

6. The IC package of claim 1, wherein the standoff element is a standoff post comprising dummy silicon.

7. The IC package of claim 1, wherein the standoff element is a passive element.

8. The IC package of claim 1, wherein the standoff element is attached to the second surface of the interposer.

9. The IC package of claim 1, further comprising an embedded layer disposed between and in contact with the first surface of the substrate and the second surface of the interposer, the embedded layer encapsulating the plurality of homogeneous solder balls and at least a portion of the standoff element.

10. An integrated circuit (IC) package, comprising:
a substrate including a first surface and a second surface opposite the first surface;
an interposer including a first surface and a second surface opposite the first surface;
a plurality of homogeneous solder balls disposed between the first surface of the substrate and the second surface of the interposer, the plurality of homogeneous solder balls providing physical and electrical contact between the substrate and the interposer;
an IC die disposed on the first surface of the substrate, and
a standoff element disposed between the IC die and the second surface of the interposer, the standoff element providing a predefined minimum spacing between the IC die and the second surface of the interposer.

11. The IC package of claim 10, wherein the standoff element is a standoff post comprising dummy silicon.

12. The IC package of claim 11, wherein the standoff post is attached to the second surface of the interposer.

13. The IC package of claim 11, wherein the standoff post is attached to a surface of the IC die.

14. The IC package of claim 10, wherein the standoff element is a solder mask attached to the second surface of the interposer.

15. The IC package of claim 10, wherein the standoff element is a passive element attached to the second surface of the interposer.

16. The IC package of claim 1, further comprising an embedded layer disposed between and in contact with the first surface of the substrate and the second surface of the interposer, the embedded layer encapsulating the plurality of homogeneous solder balls, the IC die, and at least a portion of the standoff element.

17. A method of manufacturing an integrated circuit (IC) package, comprising:
coupling a plurality of conductive elements to a surface of an interposer;
attaching a standoff element to the surface of the interposer or the substrate;
coupling the plurality of conductive elements to a surface of a substrate, the standoff element defining a minimum gap between the surface of the interposer and the surface of the substrate; and
injecting encapsulation material between the surface of the interposer and the surface of the substrate to form an embedded layer in contact with the surface of the interposer and the surface of the substrate, the embedded layer encapsulating the plurality of conductive elements and at least a portion of the standoff element.

18. The method of claim 17, wherein the standoff element is positioned between the surface of the interposer and an IC die coupled to the surface of the substrate.

19. The method of claim 18, further comprising coupling the IC die to the surface of the substrate.

20. The method of claim 17, further comprising singulation of the IC package wherein the standoff element is removed from the IC package during singulation.
